(19) United States
(12) Patent Application Publication
(10) Pub. No.: US 2026/0101758 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventor: Hyunsoo CHUNG, Suwon-si (KR)

(73) Assignee: SAMSUNG ELECTRONICS CO., LTD., Suwon-si (KR)

(21) Appl. No.: 19/316,374

(22) Filed: Sep. 2, 2025

(30) Foreign Application Priority Data
Oct. 4, 2024 (KR) 10-2024-0134960

(51) Int. Cl. H01L 23/552; H01L 23/00; H01L 23/31; H01L 23/48; H01L 23/498; H01L 25/04

(52) U.S. Cl. CPC H10W 42/20; H10W 20/20; H10W 74/131; H10W 90/00; H10W 90/701; H10W 90/792

(57) ABSTRACT

A semiconductor package includes: a first semiconductor chip; a second semiconductor chip above the first semiconductor chip; a shielding wall structure surrounding the first semiconductor chip at a side of the first semiconductor chip; a shielding film structure extending along a side surface of the second semiconductor chip and an upper surface of the second semiconductor chip; a first chip bonding pad between the first semiconductor chip and the second semiconductor chip and adjacent to an upper portion of the first semiconductor chip; and a second chip bonding pad between the first semiconductor chip and the second semiconductor chip and adjacent to a lower portion of the second semiconductor chip.

### CROSS-REFERENCE TO RELATED APPLICATIONS

This application is based on and claims priority under 35 U.S.C. § 119 to Korean Patent Application No. 10-2024-0134960, filed on Oct. 4, 2024, in the Korean Intellectual Property Office, the disclosure of which is incorporated by reference herein in its entirety.

### BACKGROUND

### 1. Field of the Invention

The present disclosure relates to a semiconductor package.

### 2. Description of the Related Art

With the development of electronic industry, demand for high functionalization, high speed, and miniaturization of an electronic component is increasing. To correspond to such trend, a method of stacking and mounting multiple semiconductor chips on one package wiring structure or a method of stacking a package on another package may be used. For example, a package-in-package (PIP)-type semiconductor package or a package-on-package (POP)-type semiconductor package may be used.

As a semiconductor package is highly integrated, and as a capacity of the semiconductor package is highly increased, shielding against electromagnetic interference is required. Also, an increase in the difficulty of processing the semiconductor package may cause difficulty in absorption of humidity from outside of the semiconductor package.

### SUMMARY

Provided is a semiconductor package that may have improved performance of shielding against an electromagnetic wave and may prevent humidity absorption.

Additional aspects will be set forth in part in the description which follows and, in part, will be apparent from the description, or may be learned by practice of the presented embodiments.

According to an aspect of the disclosure, a semiconductor package includes: a first semiconductor chip; a second semiconductor chip above the first semiconductor chip; a shielding wall structure surrounding the first semiconductor chip at a side of the first semiconductor chip; a shielding film structure extending along a side surface of the second semiconductor chip and an upper surface of the second semiconductor chip; a first chip bonding pad between the first semiconductor chip and the second semiconductor chip and adjacent to an upper portion of the first semiconductor chip; and a second chip bonding pad between the first semiconductor chip and the second semiconductor chip and adjacent to a lower portion of the second semiconductor chip.

According to an aspect of the disclosure, a semiconductor package includes: a redistribution substrate including a redistribution layer; a first semiconductor chip on the redistribution substrate; a first molding film surrounding the first semiconductor chip on the redistribution substrate; a second semiconductor chip above the first semiconductor chip; a passivation film extending along a side surface of the second semiconductor chip and an upper surface of the second semiconductor chip above the first molding film; a shielding wall structure penetrating the first molding film and surrounding a side surface of the first semiconductor chip, the shielding wall structure being connected to the redistribution layer; a shielding film structure extending along the passivation film above the side surface of the second semiconductor chip and the upper surface of the second semiconductor chip, the shielding film structure being connected to the shielding wall structure; and a second molding film covering the shielding film structure above the first molding film.

According to an aspect of the disclosure, a semiconductor package includes: a redistribution substrate; a first semiconductor chip on the redistribution substrate; a shielding wall structure on the redistribution substrate and surrounding a side surface of the first semiconductor chip; a second semiconductor chip above the first semiconductor chip; a wiring post between the first semiconductor chip and the shielding wall structure and electrically connecting the redistribution substrate and the second semiconductor chip; a passivation film extending along a side surface of the second semiconductor chip and an upper surface of the second semiconductor chip; a shielding film structure extending along the passivation film and connected to the shielding wall structure; a first chip penetration via penetrating at least a portion of the first semiconductor chip and connected to the second semiconductor chip; a first chip bonding pad between the first semiconductor chip and the second semiconductor chip and connected to the first chip penetration via; and a second chip bonding pad between the first semiconductor chip and the second semiconductor chip and adjacent to a lower portion of the second semiconductor chip, the second chip bonding pad contacting the first chip bonding pad.

### BRIEF DESCRIPTION OF THE DRAWINGS

The above and/or other aspects, features, and advantages of certain embodiments will be more apparent and more readily appreciated from the following description, taken in conjunction with the accompanying drawings, in which:

FIG. 1 illustrates an example layout diagram for describing a semiconductor package according to some example embodiments;

FIG. 2 illustrates a cross section taken along line A-A of FIG. 1;

FIG. 3 illustrates a cross section taken along line A-A of FIG. 1 for describing a semiconductor package according to some other example embodiments;

FIG. 4 illustrates a cross section taken along line A-A of FIG. 1 for describing a semiconductor package according to still some other example embodiments;

FIG. 5 illustrates a cross section taken along line A-A of FIG. 1 for describing a semiconductor package according to still some other example embodiments;

FIG. 6 illustrates a cross section taken along line A-A of FIG. 1 for describing a semiconductor package according to still some other example embodiments; and

FIGS. 7 through 16 illustrate an intermediate operation for describing a method for manufacturing a semiconductor package according to some example embodiments, which is illustrated in FIG. 2.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their disclosure in the best way. Thus, since example embodiments described in the present disclosure and configurations illustrated in the accompanying drawings are merely example embodiments and do not represent all of the technical spirit of the present disclosure, various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. The terms are not to exclude in advance a possibility that one or more other features, numbers, operations, actions, elements, components, or combinations thereof may be present or added.

In the following descriptions, terms in a singular form include terms in a plural form unless an apparently and contextually conflicting description is present. Terms including an ordinal number such as “first” or “second” used in the present specification may be used to describe various elements. However, the elements may not be limited by the terms including the ordinal number. The terms may be used to contextually distinguish one element from another element in a part of the specification. Within a range of the technical spirit of the present disclosure, a first element may be referred to as a second element in another part of the specification, and reversely, the second element may be referred to as the first element in another part of the specification. Also, in the accompanying drawings, shapes, sizes, or the like of elements in the drawings may be exaggerated for clearer description.

An expression, such as an upper side, an upper portion, a lower side, a lower portion, a side surface, a front surface, or a rear surface, is based on directions illustrated in the drawings and that the expression may be changed when a direction of a corresponding object is changed. Shapes, sizes, or the like of elements in the drawings may be exaggerated for clearer description.

Hereinafter, the example embodiments of the present disclosure will be described with reference to the drawings.

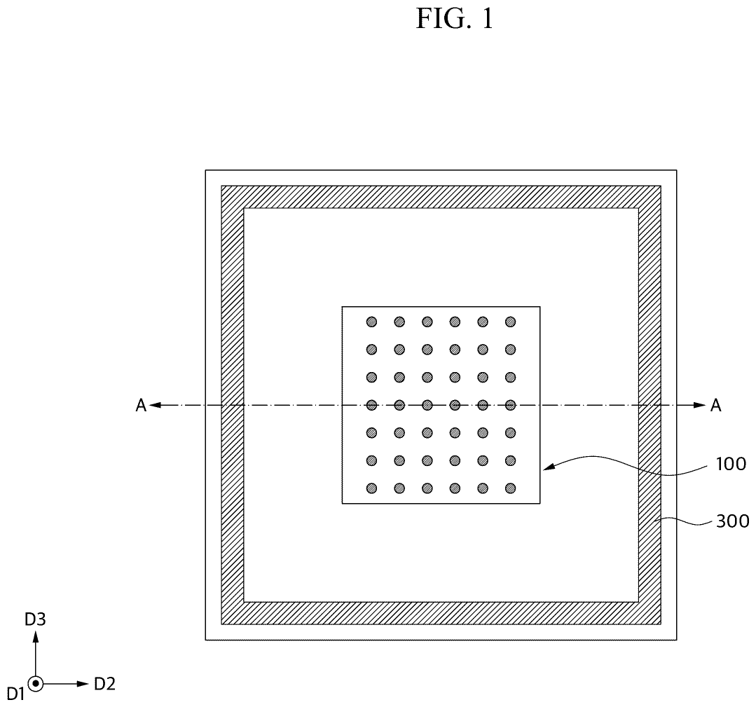

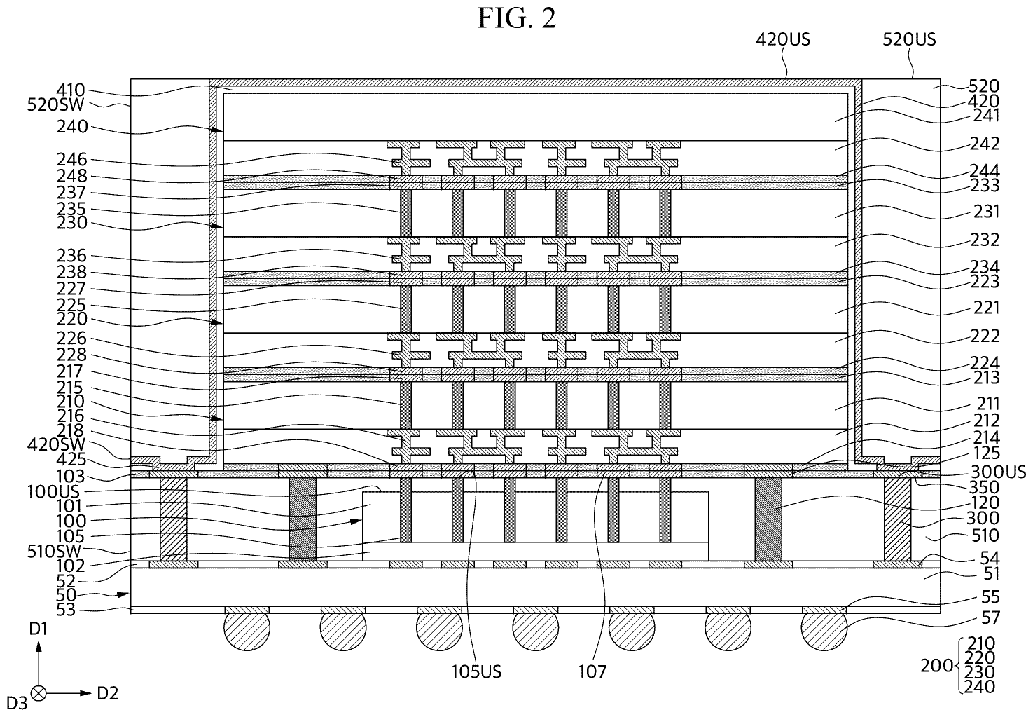

FIG. 1 illustrates an example layout diagram for describing a semiconductor package according to some example embodiments. FIG. 2 illustrates a cross section taken along line A-A of FIG. 1.

Referring to FIGS. 1 and 2, the semiconductor package according to some example embodiments may include a redistribution substrate 50, a first semiconductor chip 100, a second semiconductor chip 200, a shielding wall structure 300, a passivation film 410, a shielding film structure 420, a first molding film 510, and a second molding film 520.

According to some example embodiments, the redistribution substrate 50, the first semiconductor chip 100, and the second semiconductor chip 200 may be vertically stacked. For example, the redistribution substrate 50, the first semiconductor chip 100, and the second semiconductor chip 200 may be sequentially stacked in a first direction D1. The first direction D1 may be perpendicular to an upper surface 100US of the first semiconductor chip. The first direction D1 may be perpendicular to an upper surface or a lower surface of the redistribution substrate 50.

According to some example embodiments, the redistribution substrate 50 may be disposed below the first semiconductor chip 100 and the second semiconductor chip 200. The redistribution substrate 50 may be electrically connected to the first semiconductor chip 100 and the second semiconductor chip 200. The first semiconductor chip 100 and the second semiconductor chip 200 may send and receive an electrical signal to and from an external device through the redistribution substrate 50.

According to some example embodiments, the redistribution substrate 50 may be a wiring structure for a package. For example, the redistribution substrate 50 may be a printed circuit board (PCB), a ceramic substrate, or an interposer. In some embodiments, the redistribution substrate 50 may be a wiring structure for a wafer level package (WLP) manufactured at a wafer level. The redistribution substrate 50 may be a semiconductor chip including a semiconductor device. The redistribution substrate 50 may function as a support substrate of the semiconductor package.

In some example embodiments, the redistribution substrate 50 may be, for example, a glass substrate, a ceramic substrate, or a plastic substrate. As an example, the redistribution substrate 50 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric).

According to some example embodiments, the redistribution substrate 50 may be, for example, bulk silicon or silicon-on-insulator (SOI). As another example, the redistribution substrate 50 may be a silicon substrate. As still another example, the redistribution substrate 50 may include, for example, silicon germanium, silicon germanium on insulator (SGOI), indium antimonide, lead telluride, indium arsenide, gallium arsenide, or gallium antimonide.

According to some example embodiments, the redistribution substrate 50 may include a conductive area, for example, a well doped with an impurity or a structure doped with an impurity. The redistribution substrate 50 may have various element isolation structures such as a shallow trench isolation (STI) structure.

According to some example embodiments, the redistribution substrate 50 may include a substrate body portion 51, an upper insulation film 52, and a lower insulation film 53.

According to some example embodiments, when the redistribution substrate 50 is the printed circuit board, the substrate body portion 51 may be formed of at least one material selected from a phenolic resin, an epoxy resin, and polyimide. The redistribution substrate 50 may include at least one material selected from tetrafunctional epoxy, polyphenylene ether, epoxy/polphenylene oxide, bimaleimide triazine (BT), Thermount, cyanate ester, and a liquid crystal polymer.

According to some example embodiments, the substrate body portion 51 may include a photoimageable dielectric. As an example, the substrate body portion 51 may include a photosensitve polymer. The photosensitive polymer may be formed of, for example, at least one of photosensitive polyimide, polybenzoxazole, a phenolic polymer, and a benzocyclobutene-based polymer. As another example, the substrate body portion 51 may be formed of a silicon oxide film, a silicon nitride film, or a silicon oxynitride film.

According to some example embodiments, a surface of the substrate body portion 51 may be covered by the upper insulation film 52 and the lower insulation film 53. The upper insulation film 52 and the lower insulation film 53 may protect a wiring structure and other structures in the substrate body portion 51 from external impact or humidity. The upper insulation film 52 and the lower insulation film 53 may include, for example, solder resist, but embodiments are not limited thereto.

According to some example embodiments, a redistribution connection pad 54 may be disposed in the upper insulation film 52. The redistribution connection pad 54 may be electrically connected to a first chip device layer 102 of the first semiconductor chip 100, a wiring post 120, and the shielding wall structure 300. The redistribution connection pad 54 may be in contact with the wiring post 120 and the shielding wall structure 300.

In an embodiment, a substrate wiring structure may be disposed in the substrate body portion 51. The substrate wiring structure may include a wiring layer and a wiring via that connects each wiring layer. For example, the substrate wiring structure may be a multilayered structure in which two or more wiring layers or two or more wiring vias are stacked alternately. For example, the wiring layer may be extended in a second direction D2 or a third direction D3. The wiring via may connect wiring layers spaced apart in the first direction D1.

According to some example, the substrate wiring structure may include a conductive material. For example, the substrate wiring structure may include, for example, copper (Cu), aluminum (Al), silver (Ag), tin (Sn), gold (Au), nickel (Ni), lead (Pb), titanium (Ti), or an alloy of these materials, but embodiments are not limited thereto.

According to some example embodiments, an external connection terminal 57 may be formed below the redistribution substrate 50. The external connection terminal 57 may be disposed on an external connection pad 55. The external connection pad 55 may be disposed in the lower insulation film 53. The external connection terminal 57 may be in contact with the external connection pad 55. The external connection terminal 57 may include a solder ball or a solder bump. The external connection terminal 57 may have, for example, a spherical shape or an oval spherical shape, but embodiments are not limited thereto. The number of external connection terminals 57, an interval between the external connection terminals 57, disposition or a shape of the external connection terminals 57, or the like is not limited to the embodiment shown in FIG. 2 and may also vary depending on a design. The external connection terminal 57 may include, for example, tin (Sn), indium (In), bismuth (Bi), antimony (Sb), copper (Cu), silver (Ag), zinc (Zn), lead (Pb), and a combination of these materials, but embodiments are not limited thereto.

According to some example embodiments, the external connection terminal 57 may electrically connect the substrate wiring structure to the external device. Accordingly, the external connection terminal 57 may provide an electrical signal to the substrate wiring structure or provide, to the external device, an electrical signal provided from the substrate wiring structure. For example, the external connection terminal 57 may receive an electric signal that is input to the first semiconductor chip 100 and the second semiconductor chip 200. The external connection terminal 57 may receive a signal that is output by the first semiconductor chip 100 and the second semiconductor chip 200.

According to some example embodiments, the semiconductor chip 100 may be disposed on the redistribution substrate 50. The first semiconductor chip 100 may be disposed between the redistribution substrate 50 and the second semiconductor chip 200 in the first direction D1. The first semiconductor chip 100 may be electrically connected to the redistribution substrate 50 and the second semiconductor chip 200.

According to some example embodiments, the first semiconductor chip 100 may be an integrated circuit (IC) in which, for example, hundreds to millions or more of semiconductor devices are integrated in one chip. As an example, the first semiconductor chip 100 may include a logic chip. The first semiconductor chip 100 may be, for example, a microprocessor, an analog element, a digital signal processor, or an application processor. The first semiconductor chip 100 may be, for example, a central processing unit (CPU), a graphic processing unit (GPU), a field-programmable gate array (FPGA), the digital signal processor, an encryption processor, the microprocessor, or the application processor (AP) such as a microcontroller. As another example, the first semiconductor chip 100 may be a memory chip such as a volatile memory (e.g., a dynamic random access memory (DRAM)) or a non-volatile memory (e.g., a read-only memory (ROM) or flash memory).

According to some example embodiments, the first semiconductor chip 100 may be disposed in the first molding film 510. The first semiconductor chip 100 may be covered by the first molding film 510. A side surface of the first semiconductor chip 100 and the upper surface 100US of the first semiconductor chip may be covered by the first molding film 510. The side surface of the first semiconductor chip 100 may refer to or may correspond to surfaces crossing the upper surface 100US of the first semiconductor chip and disposed in the second direction D2 and the third direction D3. Above the redistribution substrate 50, the upper surface 100US of the first semiconductor chip may be disposed lower than an upper surface 300US of the shielding wall structure. The upper surface 100US of the first semiconductor chip may be disposed to be further adjacent to the upper surface 300US of the shielding wall structure when compared to the upper surface 300US of the shielding wall structure. A first width of the first semiconductor chip 100 may be smaller than a second width of the second semiconductor chip 200.

According to some example embodiments, the first semiconductor chip 100 may include a first chip substrate 101, a first chip device layer 102, and a first chip penetration via 105. The semiconductor chip 100 may be electrically connected to the redistribution substrate 50 through the redistribution connection pad 54.

According to some example embodiments, the first chip substrate 101 may be, as an example, bulk silicon or SOI. As another example, the first chip substrate 101 may be a silicon substrate. As still another example, the first chip substrate 101 may include, for example, silicon germanium, SGOI, indium antimonide, lead telluride, indium arsenide, gallium arsenide, or gallium antimonide, but embodiments are not limited thereto.

According to some example embodiments, the first chip substrate 101 may include a conductive area, for example, a well doped with an impurity or a structure doped with an impurity. The first chip substrate 101 may have various element isolation structures such as the STI structure.

According to some example embodiments, the first chip device layer 102 may be disposed below the first chip substrate 101. The first chip device layer 102 may include various types of a plurality of individual devices and an inter-layer insulation film. An individual device may include various microelectronic devices, for example, a metal-oxide-semiconductor filed effect transistor (MOFSET) such as a complementary metal-insulator-semiconductor (CMOS) transistor, a system large-scale integration (LSI) device, a flash memory, a DRAM, a static random access memory (SRAM), an electrically erasable and programmable read-only memory (EEPROM), a phase-change random access memory (PRAM), a resistive random access memory (RRAM), an image sensor such as a CMOS imaging sensor (CIS), a micro-electro-mechanical system (MEMS), an active element, a passive element, or the like.

According to some example embodiments, the individual devices of the first chip device layer 102 may be electrically connected to the conductive area which is formed in the first chip substrate 101. The individual devices of the first chip device layer 102 may be electrically separated from other neighboring individual devices by insulation films. The first chip device layer 102 may include a wiring structure that electrically connects at least two of the plurality of individual devices or electrically connects the plurality of individual devices and the conductive area of the first chip substrate 101. An insulation layer (for protecting the wiring structure in the first chip device and other structures in the first chip device layer 102 from, for example, external impact or humidity) may be formed below the first chip device layer 102.

According to some example embodiments, the first chip penetration via 105 may penetrate at least a portion of the first chip substrate 101. For example, the first chip penetration via 105 may penetrate the first chip substrate 101. The first chip penetration via 105 may be extended in the first direction D1. The first chip penetration via 105 may be connected to the wiring structure which is provided in the first chip device layer 102.

According to some example embodiments, the first chip penetration via 105 may penetrate the upper surface 100US of the first semiconductor chip. Above the redistribution substrate 50, an upper surface 105US of the first chip penetration via may be disposed higher than the upper surface 100US of the first semiconductor chip. The upper surface 105US of the first chip penetration via and the upper surface 300US of the shielding wall structure may be disposed on an identical plane. At least a portion of the first chip penetration via 105 may be surrounded by the first molding film 510. At least a portion of the first chip penetration via 105, which protrudes to an outside of the first semiconductor chip 100 by penetrating the upper surface 100US of the first semiconductor chip, may be covered by the first molding film 510.

According to some example embodiments, the first chip penetration via 105 may be connected to a first chip bonding pad 107. The first chip penetration via 105 may be in contact with the first chip bonding pad 107. The first chip penetration via 105 may electrically connect, for example, the first chip device layer 102 and the first chip bonding pad 107. The first semiconductor chip 100 and the second semiconductor chip 200 may be electrically connected through the first chip bonding pad 107 and the first chip penetration via 105. The first chip bonding pad 107 may be disposed above the first semiconductor chip 100. The first chip bonding pad 107 may be disposed in a first chip bonding film 103.

According to some example embodiments, the first chip penetration via 105 may include a barrier film formed on a surface of a pillar shape and a buried conductive layer filling an inside of the barrier film. The barrier film may include, for example, at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB), but embodiments are not limited thereto. The buried conductive layer may include, for example, at least one of copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tunsten (W) alloy, nickel (Ni), ruthenium (Ru), and cobalt (Co), but embodiments are not limited thereto.

According to some example embodiments, an insulation film may be additionally interposed between the first chip substrate 101 and the first chip penetration via 105. The insulation film may include, for example, an oxide film, a nitride film, a carbide film, a polymer, or a combination of these films, but embodiments are not limited thereto.

According to some example embodiments, the wiring post 120 may be disposed at a side of the first semiconductor chip 100. For example, the wiring post 120 may be disposed at the side of the first semiconductor chip 100 in the second direction D2 or the third direction D3 parallel to the upper surface or the lower surface of the redistribution substrate 50. The wiring post 120 may penetrate the first molding film 510 in the first direction D1. The wiring post 120 may be surrounded by the first molding film 510. The wiring post 120 may be disposed between the first semiconductor chip 100 and the shielding wall structure 300. According to some example embodiments, the wiring post 120 may be disposed to be further adjacent to the first semiconductor chip 100 than the shielding wall structure 300.

According to some example embodiment, the wiring post 120 may electrically connect the second semiconductor chip 200 and the redistribution substrate 50. The wiring post 120 may be in contact with a post bonding pad 125. The wiring post 120 may be extended between the post bonding pad 125 and the redistribution connection pad 54 in the first direction D1. The second semiconductor chip 200 may be electrically connected to the redistribution substrate 50 through the wiring post 120 and the post bonding pad 125.

According to some example embodiments, the wiring post 120 may include a conductive material. The wiring post 120 may include, for example, copper (Cu) and a copper alloy. For example, the wiring post 120 may include, for example, aluminum (Al), silver (Ag), tin (Sn), gold (Au), nickel (Ni), lead (Pb), titanium (Ti), or the alloy of these materials, but embodiments are not limited thereto.

According to some example embodiments, the second semiconductor chip 200 may be disposed above the first semiconductor chip 100. Above the first molding film 510, the second semiconductor chip 200 may be electrically connected to the first semiconductor chip 100. The second semiconductor chip 200 may be stacked above the first semiconductor chip 100 in the first direction D1. The second semiconductor chip 200 may be surrounded by the second molding film 520.

According to some example embodiments, the second semiconductor chip 200 may be an integrated circuit (IC) in which, for example, hundreds to millions or more of semiconductor devices are each integrated in one chip. For example, the second semiconductor chip 200 may include a memory chip such as a volatile memory or a non-volatile memory. The second semiconductor chip 200 may be a high bandwidth memory (HBM).

According to some example embodiments, the second semiconductor chip 200 may include a plurality of dies such as a first die 210, a second die 220, a third die 230, and a fourth die 240. The second semiconductor chip 200 may include a plurality of memory chips stacked in the first direction D1. As an example, each of the first die 210, the second die 220, the third die 230, and the fourth die 240 may be a memory chip. FIG. 2 illustrates that the second semiconductor chip 200 includes four dies, but embodiments of the disclosure are not limited to this example. The number of the dies included in the second semiconductor chip 200 may be variously changed depending on example embodiments.

According to some example embodiments, the first die 210, the second die 220, the third die 230, and the fourth die 240 each may be a non-volatile memory chip such as a DRAM or a SRAM. As another example, each of the first die 210, the second die 220, the third die 230, and the fourth die 240 may be a non-volatile memory chip such as a flash memory, a phase-change RAM (PRAM), a magnetoresistive RAM (MRAM), a ferroelectric RAM (FeRAM), or a resistive RAM (RRAM).

According to some example embodiments, the first die 210, the second die 220, the third die 230, and the fourth die 240 may be stacked above the first semiconductor chip 100 in the first direction D1. The first die 210, the second die 220, the third die 230, and the fourth die 240 may be electrically connected to each other or electrically connected to the first semiconductor chip 100 or the redistribution substrate 50 through first to fourth die lower connection pads 218, 228, 238, and 248 and first to third die upper connection pads 217, 227, and 237.

According to some example embodiments, the first die 210 may include a first die substrate 211, a first die device layer 212, a first die penetration via 215, a first die upper connection pad 217, and a first die lower connection pad 218. The first die 210 may be connected to the first semiconductor chip 100 or the redistribution substrate 50 through the first die lower connection pad 218. The first die lower connection pad 218 may be disposed to a lower portion of the second semiconductor chip 200. The first die lower connection pad 218 may be disposed at a lower portion of the first die 210. The first die lower connection pad 218 may be a second chip bonding pad 218 electrically connecting the second semiconductor chip 200 and the first semiconductor chip 100.

According to some example embodiments, the first chip bonding pad 107 and the second chip bonding pad 218 may be disposed between the first semiconductor chip 100 and the second semiconductor chip 200. The first chip bonding pad 107 may be disposed to be further adjacent to an upper portion of the first semiconductor chip 100 when compared to the second chip bonding pad 218. The second chip bonding pad 218 may be disposed to be further adjacent to the lower portion of the second semiconductor chip 200 when compared to the first chip bonding pad 107.

According to some example embodiments, the first semiconductor chip 100 and the second semiconductor chip 200 may be connected with a hybrid bonding scheme. More specifically, the first semiconductor chip 100 and the first die 210 may be connected with the hybrid bonding scheme. For example, the first die lower connection pad 218 and the first chip bonding pad 107 may be in contact, so that the first semiconductor chip 100 and the first die 210 may bonded. A first die lower bonding film 214 of the first die 210 and the first chip bonding film 103 may be directly bonded.

According to some example embodiments, the first die lower bonding film 214 and the first chip bonding film 103 may be formed of different materials among silicon oxide, silicon nitride, silicon carbonitride, and silicon oxycarbonitride. The first die lower bonding film 214 and the first chip bonding film 103 may include, for example, a non-conductive film (NCF), a non-conductive paste (NCP), an insulating polymer, or an epoxy resin, but embodiments are not limited thereto. Each of the first die lower bonding film 214 and the first chip bonding film 103 may be tape for fixing the first semiconductor chip 100 and the second semiconductor chip 200 to each other. Each of the first die lower bonding film 214 and the first chip bonding film 103 may be, for example, tape including an epoxy component.

According to some example embodiments, the first die substrate 211 may be, as an example, bulk silicon or SOI. As another example, the first die substrate 211 may be a silicon substrate. As still another example, the first die substrate 211 may include,, for example, silicon germanium, SGOI, indium antimonide, lead telluride, indium arsenide, gallium arsenide, or gallium antimonide.

According to some example embodiments, the first die substrate 211 may include a conductive area, for example, a well doped with an impurity or a structure doped with an impurity. The first die substrate 211 may have various element isolation structures such as a STI structure.

According to some example embodiments, the first die device layer 212 may be disposed below the first die substrate 211. The first die device layer 212 may include various types of a plurality of individual devices and an inter-layer insulation film. An individual device may include various microelectronic devices, for example, the MOFSET such as the CMOS transistor, the LSI device, a flash memory, a DRAM, an SRAM, an EEPROM, a PRAM, an RRAM, an image sensor such as the CIS, the MEMS, an active element, a passive element, or the like.

According to some example embodiments, the individual devices of the first die device layer 212 may be electrically connected to the conductive area which is formed in the first die substrate 211. The individual devices of the first die device layer 212 may be electrically separated from other neighboring individual devices by insulation films. The first die device layer 212 may include a first die wiring structure 216 electrically connecting at least two of the plurality of individual devices or connecting the plurality of individual devices and the conductive area of the first die substrate 211.

According to some example embodiments, an insulation layer (for protecting the first die wiring structure 216 and other structures in the first die device layer 212 from, for example, external impact or humidity) may be formed on the first die device layer 212. The insulation layer may expose a portion of an upper surface of the first die lower connection pad 218.

According to some example embodiments, the first die penetration via 215 may penetrate the first die substrate 211. The first die penetration via 215 may be extended from an upper surface of the first die substrate 211 toward a lower surface of the first die substrate 211. The first die penetration via 215 may be connected to the first die wiring structure 216 which is provided in the first die device layer 212.

According to some example embodiments, the first die penetration via 215 may include a barrier film formed on a surface of a pillar shape and a buried conductive layer filling an inside of the barrier film. The barrier film may include, for example, at least one of titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boride (NiB), but embodiments are not limited thereto. The buried conductive layer may include, for example, at least one of copper (Cu), a copper (Cu) alloy such as copper-tin (CuSn), copper-magnesium (CuMg), copper-nickel (CuNi), copper-palladium (CuPd), copper-gold (CuAu), copper-rhenium (CuRe), and copper-tungsten (CuW), tungsten (W), a tunsten (W) alloy, nickel (Ni), ruthenium (Ru), and cobalt (Co), but embodiments are not limited thereto.

According to some example embodiments, an insulation film may be additionally interposed between the first die substrate 211 and the first die penetration via 215. The insulation film may include, for example, an oxide film, a nitride film, a carbide film, a polymer, or a combination of these films, but embodiments are not limited thereto.

According to some example embodiments, the first die wiring structure 216 may include a metallic wiring layer and a via plug. For example, the first die wiring structure 216 may have a multilayered structure in which two or more metallic wiring layers or two or more via plugs are stacked alternately.

According to some example embodiments, the first die lower connection pad 218 may be disposed below the first die device layer 212. The first die lower connection pad 218 may be electrically connected to the first die wiring structure 216 in the first die device layer 212. The first die lower connection pad 218 may be electrically connected to the first die penetration via 215 through the first die wiring structure 216. The first die lower connection pad 218 may include at least one selected from aluminum (Al), copper (Cu), nickel (Ni), tungsten (W), platinum (Pt), and gold (Au).

According to some example embodiments, the first die lower connection pad 218 may be surrounded by the first die lower bonding film 214. The first die lower bonding film 214 may be disposed below the first die device layer 212. The first die lower bonding film 214 may cover a lower surface of the first die device layer 212.

According to some example embodiments, the first die upper connection pad 217 (which is electrically connected to the first die penetration via 215) may be formed on the upper surface of the first die substrate 211. The first die upper connection pad 217 may be formed of a material identical to that of the first die lower connection pad 218. In an embodiment, an upper passivation layer may be formed on the upper surface of the first die substrate 211 so as to surround a portion of a side surface of the first die upper connection pad 217. The upper passivation layer may expose a portion of an upper surface of the first die upper connection pad 217.

According to some example embodiments, the first die upper connection pad 217 may be surrounded by a first die upper bonding film 213. In an embodiment, the first die upper bonding film 213 may be disposed on the first die substrate 211. In an embodiment, the first die lower bonding film 214 may cover the upper surface of the first die substrate 211.

According to some example embodiments, the second die 220 may be disposed on the first die 210. According to some example embodiments, the second die 220 may include a second die substrate 221, a second die device layer 222, a second die penetration via 225, a second die upper connection pad 227, and a second die lower connection pad 228. The second die 220 may be electrically connected to the first die 210 through the second die lower connection pad 228 and the first die upper connection pad 217 which are disposed between the first die 210 and the second die 220. In an embodiment, the second die 220 may be connected to the first die 210 by the hybrid bonding scheme.

According to some example embodiments, the third die 230 may be disposed on the second die 220. According to some example embodiments, the third die 230 may include a third die substrate 231, a third die device layer 232, a third die penetration via 235, a third die upper connection pad 237, and a third die lower connection pad 238. The third die 230 may be electrically connected to the second die 220 through the third die lower connection pad 238 and the second die upper connection pad 227 which are disposed between the second die 220 and the third die 230. In an embodiment, the third die 230 may be connected to the second die 220 with the hybrid bonding scheme.

According to some example embodiments, the fourth die 240 may be disposed on the third die 230. The fourth die 240 may include a fourth die substrate 241, a fourth die device layer 242, and a fourth die lower connection pad 248. The fourth die 240 may be electrically connected to the third die 230 through the fourth die lower connection pad 248 and the third die upper connection pad 237 which are disposed between the third die 230 and the fourth die 240. The fourth die 240 may be connected to the third die 230 with the hybrid bonding scheme. The fourth die 240 may not include a penetration via and an upper connection pad unlike the first die 210, the second die 220, and the third die 230.

According to some example embodiments, since descriptions for the second die 220, the third die 230, and the fourth die 240 are substantially identical to a description for the first die 210, the descriptions for the second die 220, the third die 230, and the fourth die 240 will be omitted.

According to some example embodiments, the shielding wall structure 300 may be disposed in the first molding film 510. A side surface of the shielding wall structure 300 may be surrounded by the first molding film 510. The side surface of the shielding wall structure 300 may refer to or may correspond to surfaces crossing the upper surface 300US of the shielding wall structure and disposed in the second direction D2 and the third direction D3. The shielding wall structure 300 may overlap the first molding film 510 in the first direction D1. The shielding wall structure 300 may electrically connect the shielding film structure 420 and the redistribution substrate 50 by penetrating the first molding film 510. Specifically, the shielding wall structure 300 may be connected to a shielding connection pad 350 and the redistribution connection pad 54. The shielding wall structure 300 may be connected to the shielding connection pad 350 and the redistribution connection pad 54. The shielding wall structure 300 may be in contact with the shielding connection pad 350 and the redistribution connection pad 54 to electrically connect the shielding film structure 420 and the redistribution substrate 50.

According to some example embodiment, the shielding wall structure 300 may be connected to the redistribution substrate 50 and the external connection terminal 57 through the redistribution connection pad 54 to receive a ground voltage. For example, the redistribution connection pad 54 (in contact with the shielding wall structure 300) may be a ground pad that provides the ground voltage. The shielding film structure 420 which is connected to the shielding wall structure 300 may receive the ground voltage.

According to some example embodiment, the shielding wall structure 300 may surround the first semiconductor chip 100 at the side of the first semiconductor chip 100. The shielding wall structure 300 surrounding the first semiconductor chip 100 may not refer to being in contact with and covering a surface of the first semiconductor chip 100 and may refer to being spaced apart from the surface of the first semiconductor chip 100 so that the shielding wall structure 300 and the first semiconductor chip 100 overlap in the second direction D2 and the third direction D3. When viewed from the upper surface 100US of the first semiconductor chip, the shielding wall structure 300 may have a ring shape surrounding the first semiconductor chip 100. For example, the shielding wall structure 300 may have a quadrangular ring shape.

According to some example embodiments, the shielding wall structure 300 may include a conductive material. For example, the shielding wall structure 300 may include, for example, copper (Cu), aluminum (Al), silver (Ag), tin (Sn), gold (Au), nickel (Ni), lead (Pb), titanium (Ti), or an alloy of these materials, but embodiments are not limited thereto.

According to some example embodiments, the passivation film 410 may be extended along the second semiconductor chip 200. The passivation film 410 may be disposed between the second semiconductor chip 200 and the shielding film structure 420. Above the first molding film 510, the passivation film 410 may cover the second semiconductor chip 200. Above the first molding film 510, the passivation film 410 may be extended along a side surface and an upper surface of the second semiconductor chip 200. In an embodiment, the passivation film 410 may cover side surfaces of the first die 210, the second die 220, the third die 230, and the fourth die 240. In an embodiment, the passivation film 410 may cover an upper surface of the fourth die 240.

According to some example embodiments, the passivation film 410 may be extended along an upper surface of the first chip bonding film 103 between the second semiconductor chip 200 and the shielding connection pad 350. The passivation film 410 may cover a portion of the upper surface of the first chip bonding film 103 between a connection part 425 and the second semiconductor chip 200. The passivation film 410 may cover a portion of the upper surface of the first chip bonding film 103 at an outside of the shielding connection pad 350. FIG. 2 illustrates the passivation film 410 as a single film, but embodiments are not limited thereto. As an example, the passivation film 410 may include a multilayered film.

According to some example embodiments, the passivation film 410 may include solder resist. As another example, the passivation film 410 may include at least one of photosensitive polyimide (PSPI), silicon oxide, silicon nitride, and silicon oxynitride.

According to some example embodiment, the shielding film structure 420 may be extended above the side surface and the upper surface of the second semiconductor chip 200. The shielding film structure 420 may be extended along the side surface and the upper surface of the second semiconductor chip 200. The shielding film structure 420 may be disposed on the passivation film 410. The shielding film structure 420 may be extended along the passivation film 410. The shielding film structure 420 may cover the passivation film 410. At least a portion of the shielding film structure 420 may be connected to the shielding wall structure 300 by penetrating the passivation film 410. FIG. 2 illustrates the shielding film structure 420 as a single film, but embodiments of the disclosure are not limited to this example. For example, the shielding film structure 420 may include a multilayered film.

According to some example embodiments, the shielding film structure 420 may include the connection part 425. The connection part 425 may be connected to the shielding connection pad 350. The connection part 425 may be in contact with the shielding connection pad 350 by penetrating the passivation film 410. In the second direction D2, a first width of the connection part 425 may be smaller than a second width of the shielding connection pad 350. The connection part 425 may not be in contact with the first chip bonding film 103. The shielding film structure 420 may be electrically connected to the shielding wall structure 300 through the connection part 425, so that the shielding film structure 420 and the shielding wall structure 300 may receive an equal voltage. For example, the shielding film structure 420 may be electrically connected to the shielding wall structure 300 to receive the ground voltage.

According to some example embodiments, an outermost side surface 420SW of the shielding film structure, a side surface 510SW of the first molding film, and a side surface 520SW of the second molding film may be disposed on an identical plane. The outermost side surface 420SW of the shielding film structure may not be covered by the second molding film 520. The outermost side surface 420SW of the shielding film structure may be exposed from the second molding film 520. An upper surface 420US of the shielding film structure and an upper surface 520US of the second molding film may be disposed on an identical plane. From the redistribution substrate 50, a first height of the upper surface 420US of the shielding film structure and a second height of the upper surface 520US of the second molding film structure may be equal. The upper surface 420US of the shielding film structure may not be covered by the second molding film 520. The upper surface 420US of the shielding film structure may be exposed from the second molding film 520.

According to some example embodiments, the shielding film structure 420 may include a conductive material. For example, the shielding film structure 420 may include, for example, copper (Cu), aluminum (Al), silver (Ag), tin (Sn), gold (Au), nickel (Ni), lead (Pb), titanium (Ti), or an alloy of these materials, but embodiments are not limited thereto.

According to some example embodiment, the shielding wall structure 300 and the shielding film structure 420 may perform shielding against a first electromagnetic wave. The shielding wall structure 300 and the shielding film structure 420 may perform the shielding to prevent emission of an electromagnetic wave generated in the semiconductor package to an outside. For example, the shielding wall structure 300 may reflect or absorb the electromagnetic wave, thus the electromagnetic interference may be reduced. The shielding wall structure 300 may prevent emission of an electromagnetic wave generated in the first semiconductor chip 100 or the second semiconductor chip 200 to the outside. The shielding wall structure 300 may perform the shielding to prevent transfer of an electromagnetic wave generated at the outside to the first semiconductor chip 100 or the second semiconductor chip 200.

According to some example embodiment, the shielding wall structure 300 and the shielding film structure 420 may suppress a flow of humidity from the outside into the semiconductor package. The shielding wall structure 300 and the shielding film structure 420 may protect the first semiconductor chip 100 and the second semiconductor chip 200 by suppressing humidity absorption of the first semiconductor chip 100 and the second semiconductor chip 200.

According to some example embodiment, the shielding wall structure 300 and the shielding film structure 420 may emit heat generated in the semiconductor package. For example, the shielding film structure 420 (which is extended along a surface of the second semiconductor chip 200) may emit heat generated on the surface of the second semiconductor chip 200 through the upper surface 420US of the shielding film structure which is exposed. The shielding wall structure 300 may emit heat (generated in the redistribution substrate 50) by transferring the heat generated in the redistribution substrate 50 to the shielding film structure 420.

According to some example embodiments, the first molding film 510 may be disposed on the redistribution substrate 50. The fist molding film 510 may surround the first semiconductor chip 100, the wiring post 120, and the shielding wall structure 300. The first molding film 510 may cover the first semiconductor chip 100. The first molding film 510 may cover the side surface of the first semiconductor chip 100 and the upper surface 100US of the first semiconductor chip. The fist molding film 510 may surround side surfaces of the first semiconductor chip 100, the wiring post 120, and the shielding wall structure 300.

According to some example embodiments, above the first molding film 510, the second molding film 520 may cover the second semiconductor chip 200. The second molding film 520 may overlap the second semiconductor chip 200 in the second direction D2 and the third direction D3. The second molding film 520 may cover the shielding film structure 420. The second molding film 520 may be disposed at a side of the shielding film structure 420. The second molding film 520 may not cover the upper surface 420US of the shielding film structure.

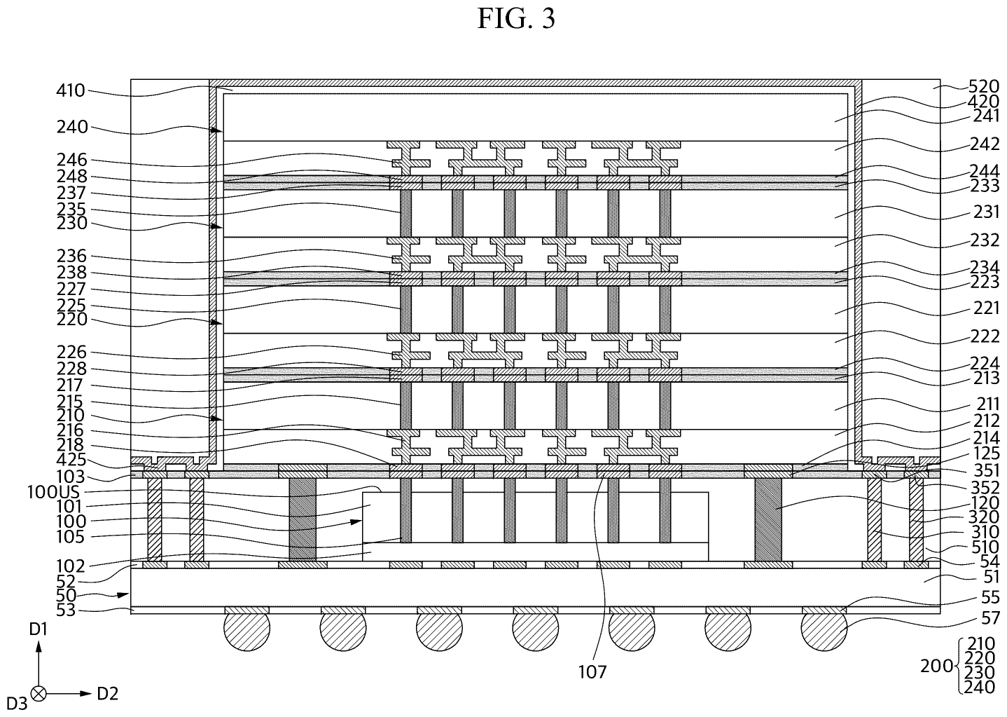

According to some example embodiments, the first molding film 510 and the second molding film 520 may include an insulation material. The first molding film 510 and the second molding film 520 may include a polymer such as a resin. The first molding film 510 and the second molding film 520 may include, for example, an epoxy molding compound (EMC), but embodiments are not limited thereto. FIG. 3 illustrates a cross section taken along line A-A of FIG. 1 for describing a semiconductor package according to some other example embodiments. In order to describe the semiconductor package according to some other example embodiments, a description will mainly focus on a point different from that described above with reference to FIGS. 1 through 2.

Referring to FIG. 3, the shielding wall structure 300 may include a first shielding wall 310 and a second shielding wall 320. The first shielding wall 310 may surround a side surface of the first semiconductor chip 100. The second shielding wall 320 may surround an outer side surface of the first shielding wall 310. The outer side surface of the first shielding wall 310 may refer to a side surface not facing the first semiconductor chip 100. The outer side surface of the first shielding wall 310 may refer to a side surface facing the second shielding wall 320 among side surfaces of the first shielding wall. The first shielding wall 310 may be disposed between the first semiconductor chip 100 and the second shielding wall 320. The second shielding wall 320 may be disposed to be further spaced apart from the first semiconductor chip 100 when compared to the first shielding wall 310.

According to some example embodiments, when viewed from the upper surfaces 100US of the first semiconductor chip, each of the first shielding wall 310 and the second shielding wall 320 may have a quadrangular ring shape surrounding the first semiconductor chip 100. When viewed from the upper surface 100US of the first semiconductor chip, a size of a quadrangular ring formed by the second shielding wall 320 may be larger than a size of a quadrangular ring formed by the first shielding wall 310.

According to some example embodiments, a first shielding connection pad 351 may be disposed on the first shielding wall 310. A second shielding connection pad 352 may be disposed on the second shielding wall 320. The first shielding connection pad 351 and the second shielding connection pad 352 may be in contact with the shielding film structure 420. The shielding film structure 420 may be connected to the first shielding connection pad 351 and the second shielding connection pad 352 by penetrating the passivation film 410.

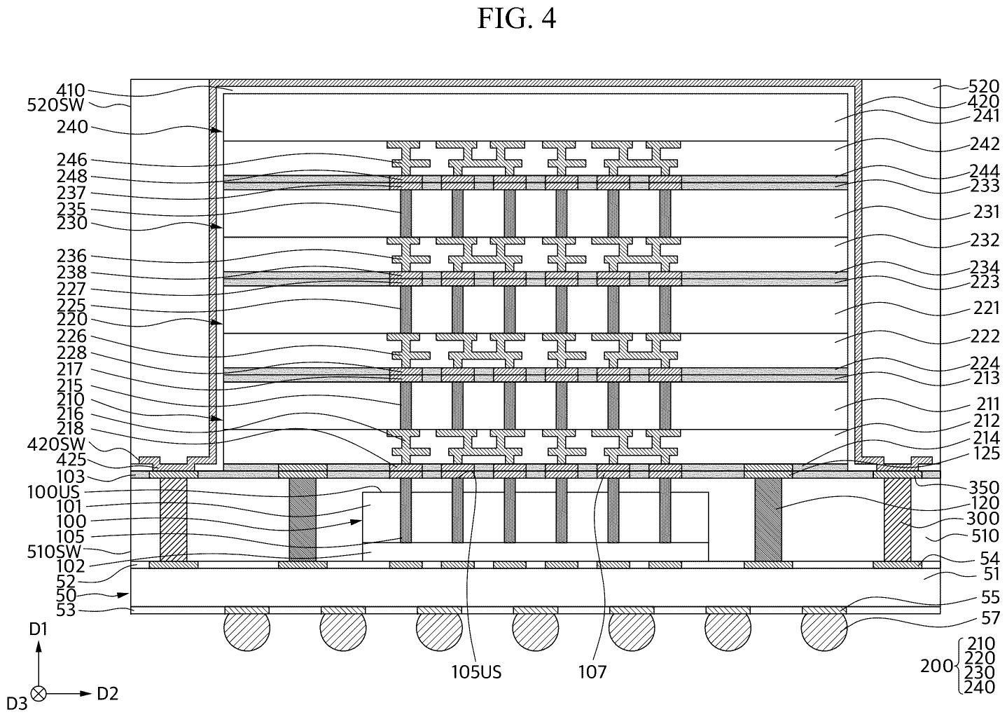

FIG. 4 illustrates a cross section taken along line A-A of FIG. 1 for describing a semiconductor package according to still some other example embodiments. In order to describe the semiconductor package according to some other example embodiments, a description will mainly focus on a point different from that described above with reference to FIGS. 1 and 2.

Referring to FIG. 4, the outermost side surface 420SW of a shielding film structure may not be disposed on an identical plane on which the side surface 510SW of a first molding film and the side surface 520SW of a second molding film are disposed. The outermost side surface 420SW of the shielding film structure may be disposed inward of the side surface 510SW of the first molding film and the side surface 520SW of the second molding film. The outermost side surface 420SW of the shielding film structure may be covered by the second molding film 520. The outermost side surface 420SW of the shielding film structure may not be exposed from the second molding film 520. The outermost side surface 420SW of the shielding film structure may be disposed to be further adjacent to a side surface of the second semiconductor chip 200 when compared to the side surface 520SW of the second molding film. The outermost side surface 420SW of the shielding film structure may be disposed to be further adjacent to a side surface of the second semiconductor chip 200 when compared to the side surface 510SW of the first molding film.

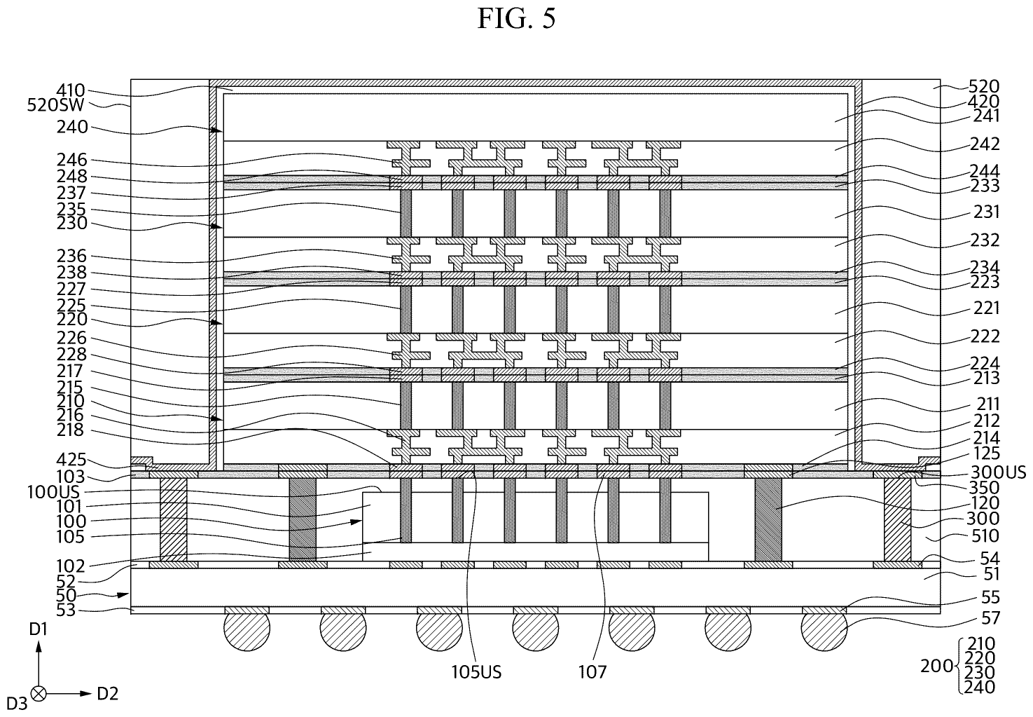

FIG. 5 illustrates a cross section taken along line A-A of FIG. 1 for describing a semiconductor package according to still some other example embodiments. In order to describe the semiconductor package according to some other example embodiments, a description will mainly focus on a point different from that described above with reference to FIGS. 1 and 2.

Referring to FIG. 5, in the second direction D2, a first width of the connection part 425 may be larger than a second width of the shielding connection pad 350. The connection part 425 may be cover an upper surface of the shielding connection pad 350. According to some example embodiments, the connection part 425 may be in contact with the first chip bonding film 103 between the second semiconductor chip 200 and the shielding connection pad 350.

According to some example embodiments, the passivation film 410 may not be extended along an upper surface of the first chip bonding film 103 between the second semiconductor chip 200 and the shielding connection pad 350. The passivation film 410 may not be extended along the upper surface of the first chip bonding film 103 between the connection part 425 and the second semiconductor chip 200. The passivation film 410 may cover a portion of the upper surface of the first chip bonding film 103 at an outside of the shielding connection pad 350.

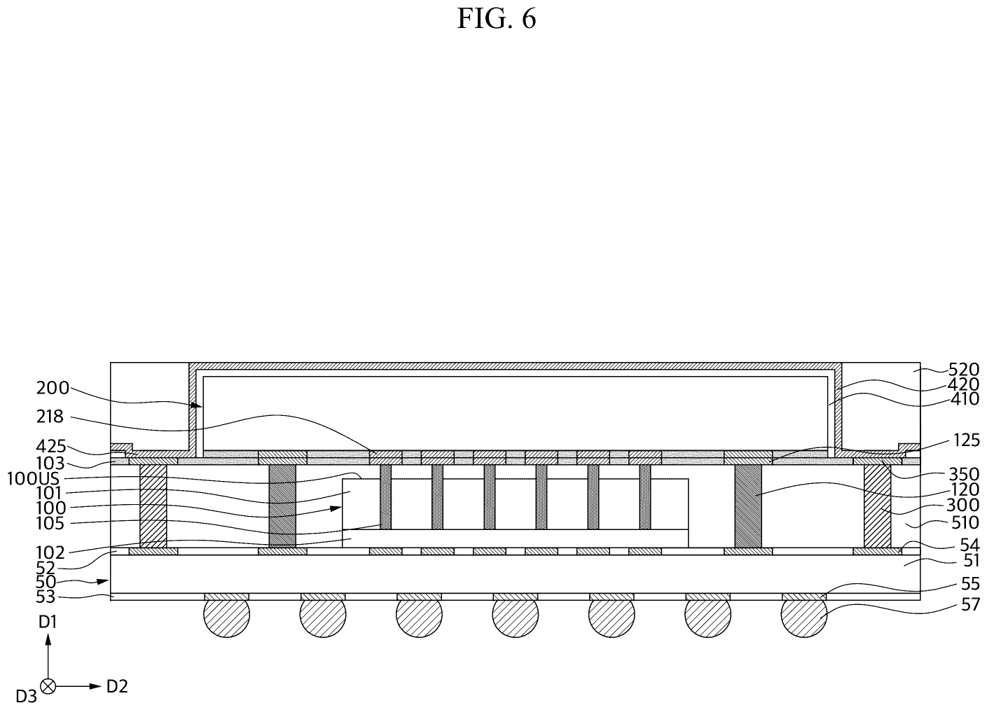

FIG. 6 illustrates a cross section taken along line A-A of FIG. 1 for describing a semiconductor package according to still some other example embodiments. In order to describe the semiconductor package according to still some other example embodiments, a description will mainly focus on a point different from that described above with reference to FIGS. 1 and 2.

Referring to FIG. 6, the second semiconductor chip 200 may not include a plurality of dies. The second semiconductor chip 200 may not include a penetration via for sending and receiving a signal to and from the plurality of dies which are disposed above and below.

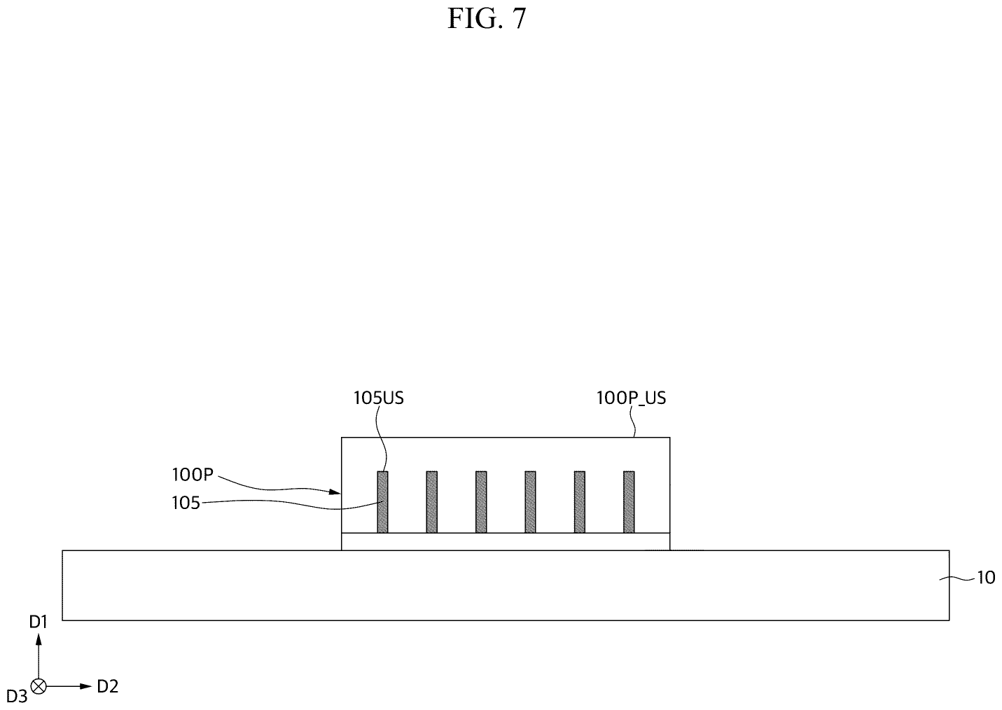

FIGS. 7 through 16 illustrate an intermediate operation for describing a method for manufacturing a semiconductor package according to some example embodiments, which is illustrated in FIG. 2.

Referring to FIG. 7, a pre-first semiconductor chip 100P may be disposed on a carrier substrate 10. The pre-first semiconductor chip 100P may have a shape before formation of the first semiconductor chip 100 (of FIG. 2). Hereinafter, a structure that appears in the intermediate operation before formed in a final structure will be described by using a term “pre-”. The carrier substrate 10 may be an insulation substrate including glass or a polymer or may be a conductive substrate including a metal. For example, the pre-first semiconductor chip 100P may be attached on the carrier substrate 10 through an adhesive layer.

According to some example embodiments, above the carrier substrate 10, an upper surface 100P_US of the pre-first semiconductor chip may be disposed higher than the upper surface 105US of a first chip penetration via. The first chip penetration via 105 may not penetrate the upper surface 100P_US of the pre-first semiconductor chip.

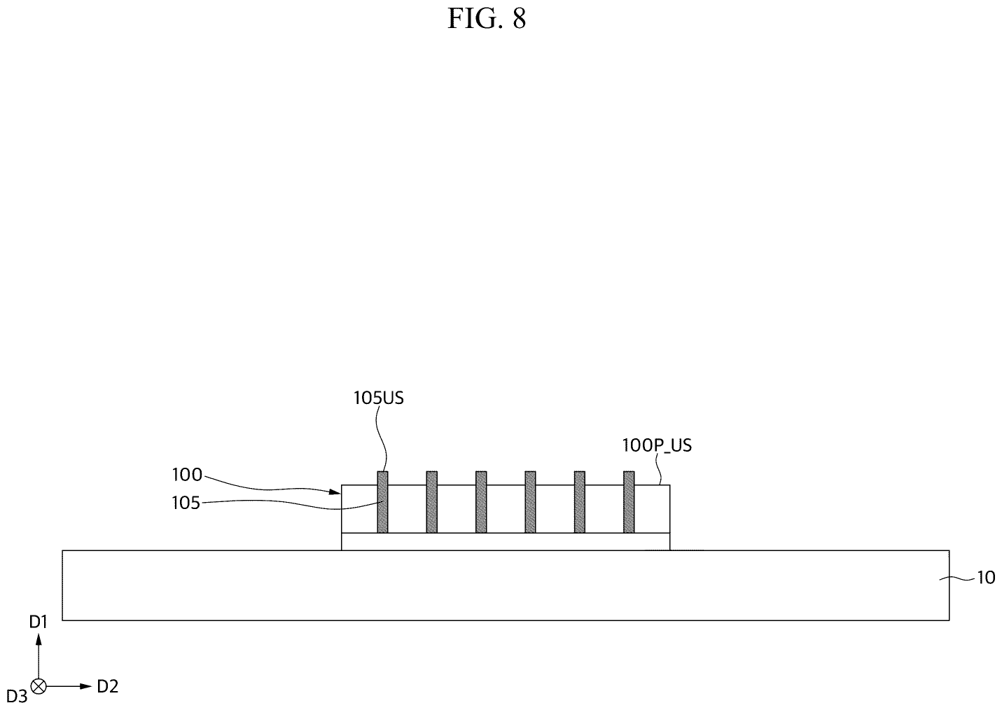

Referring to FIG. 8, a portion of the pre-first semiconductor chip 100P (of FIG. 7) is removed, so that the first semiconductor chip 100 is formed so that the first chip penetration via 105 penetrates the upper surface 100US of the first semiconductor chip. For example, the portion of the pre-first semiconductor chip 100P (of FIG. 7) may be removed through chemical mechanical polishing (CMP).

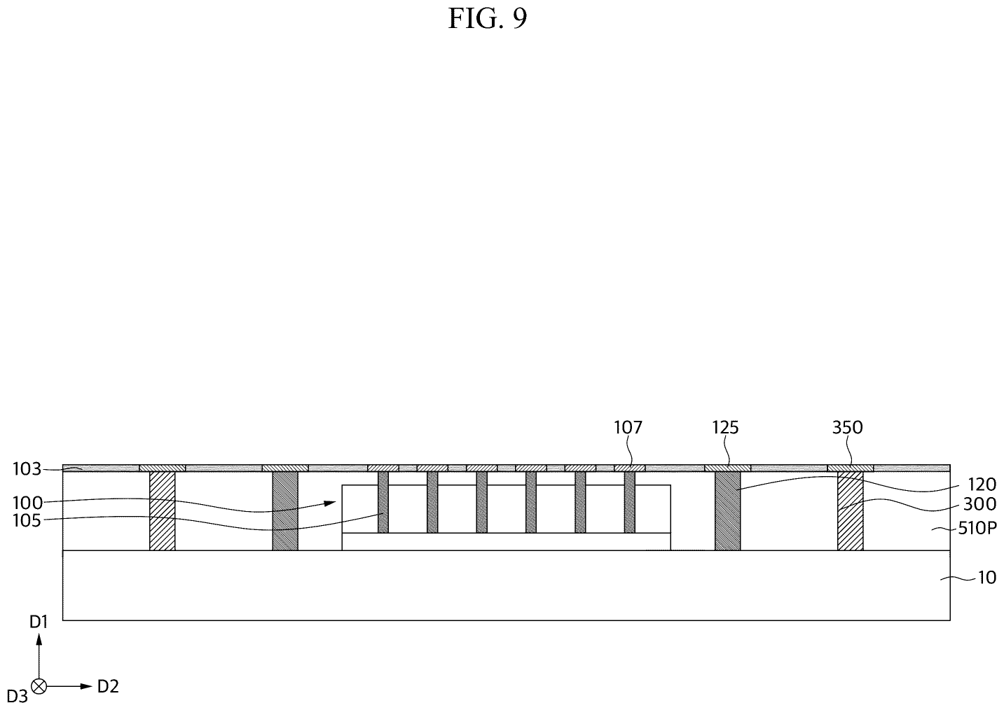

Referring to FIG. 9, a pre-first molding film 510P, the wiring post 120, the shielding wall structure 300, the first chip bonding film 103, the first chip bonding pad 107, the post bonding pad 125, and the shielding connection pad 350 may be formed above the carrier substrate 10.

According to some example embodiments, the pre-first molding film 510P may be formed so as to cover the first semiconductor chip 100 on the carrier substrate 10. The pre-first molding film 510P may cover a side surface and an upper surface of the first semiconductor chip 100 on the carrier substrate 10. A trench penetrating the pre-first molding film 510P may be formed by patterning the pre-first molding film 510P, and the wiring post 120 and the shielding wall structure 300 may be formed in the trench. The first chip bonding film 103 may be formed on the pre-first molding film 510P. The first chip bonding film 103 may be patterned, so that the first chip bonding pad 107, the post bonding pad 125, and the shielding connection pad 350 which are connected to the pre-first molding film 510P, the wiring post 120, and the shielding wall structure 300 respectively may be formed.

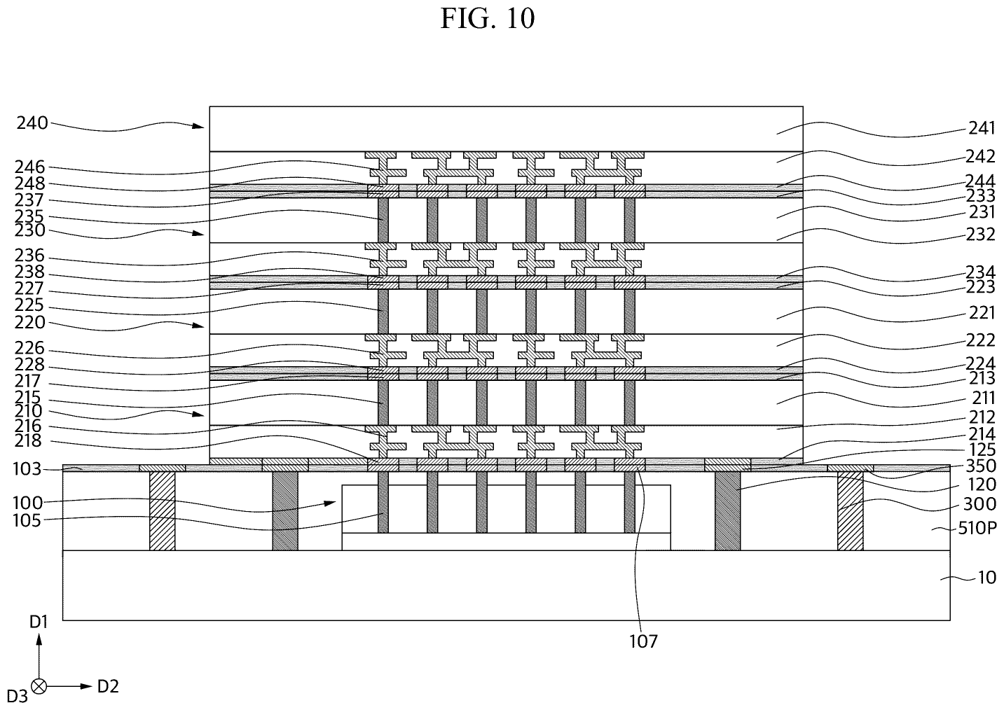

Referring to FIG. 10, the second semiconductor chip 200 may be formed above the first semiconductor chip 100, the pre-first molding film 510P, and the first chip bonding film 103. According to some example embodiments, the first die 210, the second die 220, the third die 230, and the fourth die 240 may be sequentially stacked in the first direction D1. Each of the first die 210, the second die 220, the third die 230, and the fourth die 240 may be connected with a hybrid bonding scheme. The second semiconductor chip 200 may be connected to the first semiconductor chip 100 with the hybrid bonding scheme. In one embodiment, the second chip bonding pad 218 in a lower portion of the second semiconductor chip 200 and the first chip bonding pad 107 on the first semiconductor chip 100 may be in contact with and connected to each other.

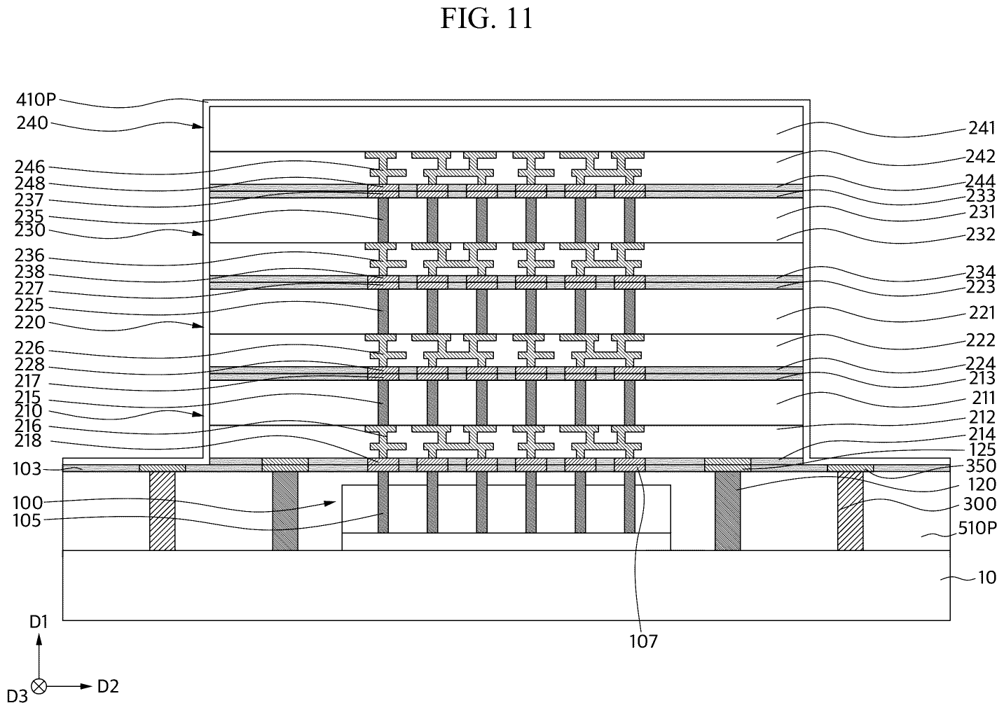

Referring to FIG. 11, a pre-passivation film 410P may be formed along a surface of the first chip bonding film 103 and the second semiconductor chip 200 above the carrier substrate 10. The pre-passivation film 410P may be extended along an upper surface of the first chip bonding film 103 and a side surface and an upper surface of the second semiconductor chip 200.

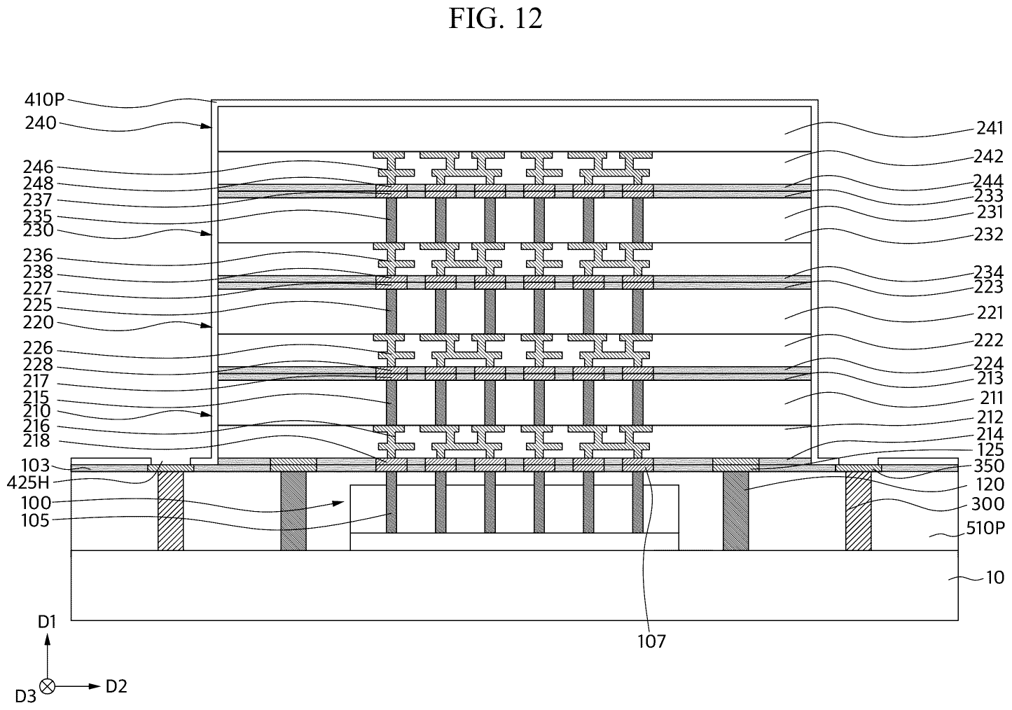

Referring to FIG. 12, the pre-passivation film 410P may be patterned, so that the shielding connection pad 350 may be exposed. A portion of the pre-passivation film 410P which covers the shielding connection pad 350 may be removed, so that a connection part hole 425H may be formed. The shielding connection pad 350 may be exposed in the connection part hole 425H.

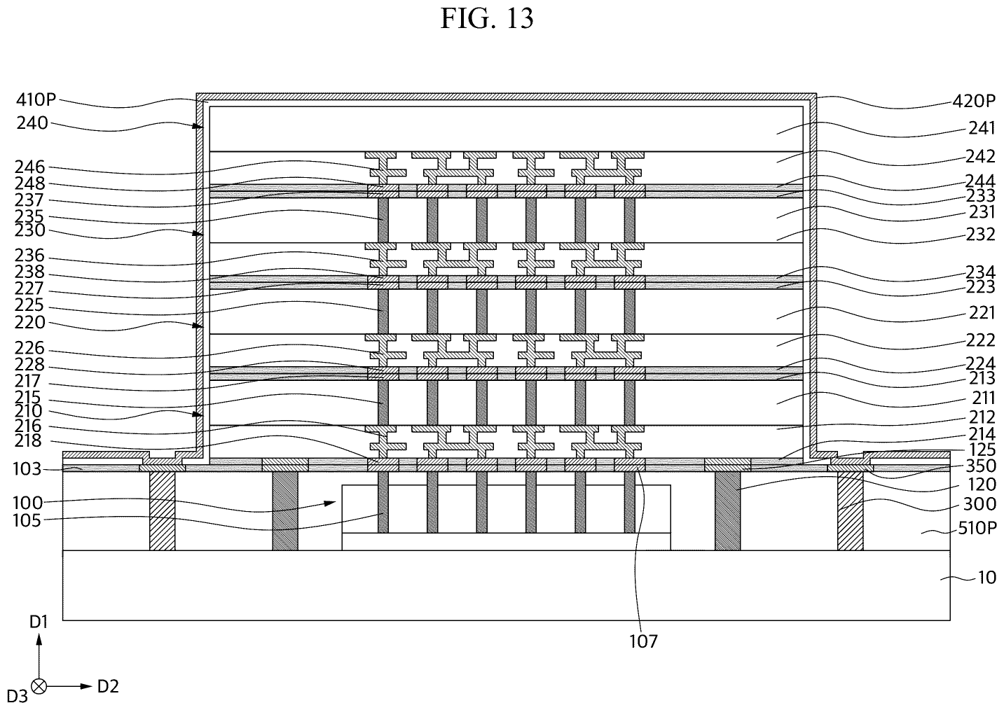

Referring to FIG. 13, a pre-shielding film structure 420P may be formed. The pre-shielding film structure 420P may be disposed on the pre-passivation film 410P. The pre-shielding film structure 420P may be extended along a profile of the pre-passivation film 410P. The pre-shielding film structure 420P may be connected to the shielding connection pad 350 in the connection part hole 425H (of FIG. 12).

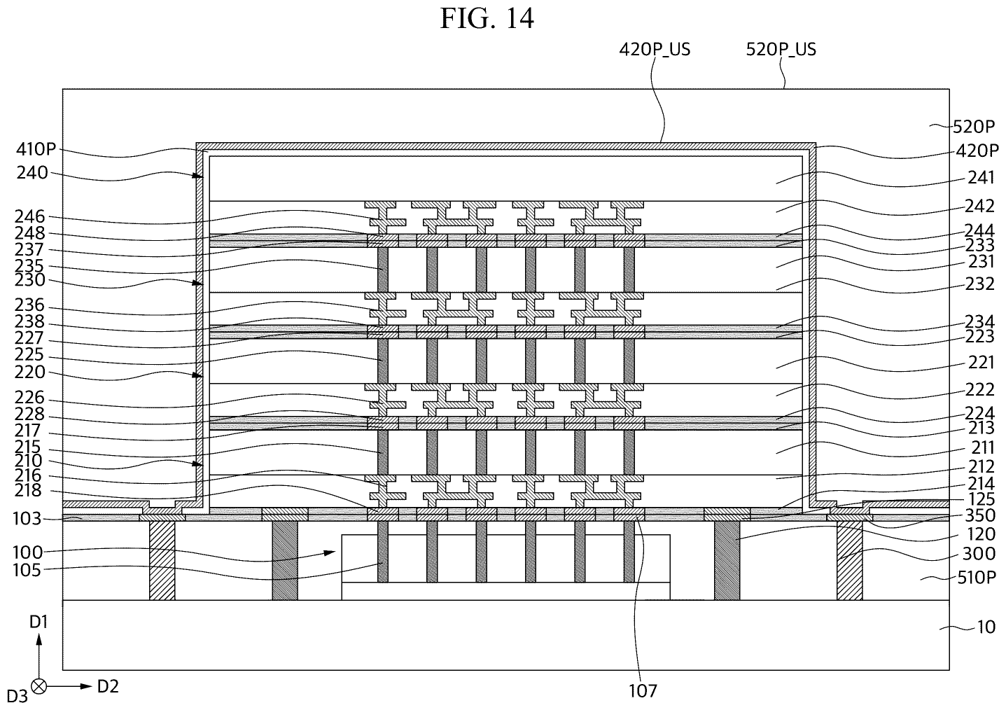

Referring to FIG. 14, a pre-second molding film 520P may be formed on the pre-shielding film structure 420P. The pre-second molding film 520P may cover the pre-shielding film structure 420P. The pre-second molding film 520P may cover an upper surface 420P_US of the pre-shielding film structure. Above the redistribution substrate 50, an upper surface 520P_US of the pre-second molding film may be disposed higher than the upper surface 420P_US of the pre-shielding film structure.

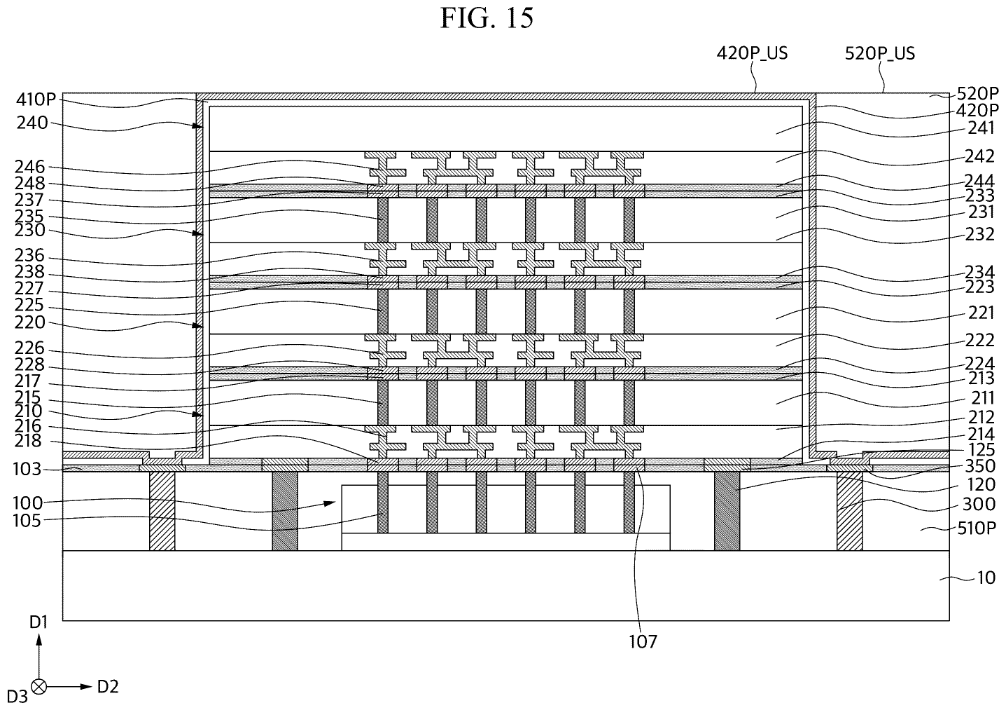

Referring to FIG. 15, a portion of the pre-second molding film 520P may be removed so that the upper surface 420P_US of the pre-shielding film structure is exposed. The upper surface 420P_US of the pre-shielding film structure and the upper surface 520P_US of the pre-second molding film may be disposed on an identical plane. For example, the portion of the pre-second molding film 520P may be removed through the CMP.

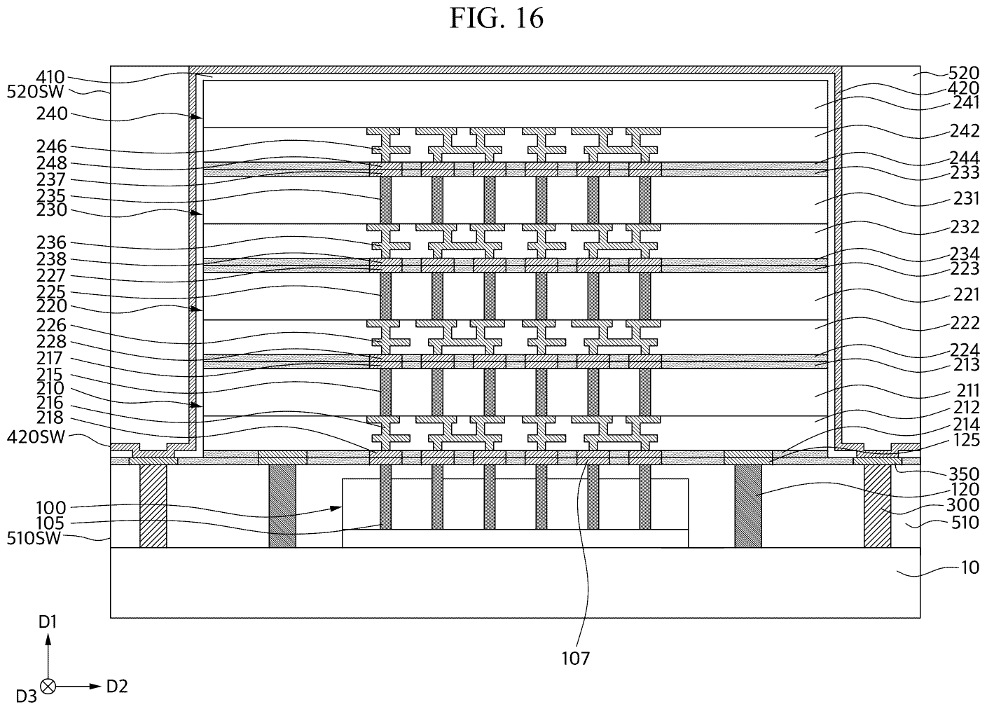

Referring to FIG. 16, the pre-first molding film 510P (of FIG. 15), the pre-second molding film 520P (of FIG. 15), the pre-passivation film 410P (of FIG. 15), and the pre-shielding film structure 420P (of FIG. 15) may be cut in the second direction D2 and the third direction D3. As the pre-first molding film 510P (of FIG. 15), the pre-second molding film 520P (of FIG. 15), the pre-passivation film 410P (of FIG. 15), and the pre-shielding film structure 420P (of FIG. 15) are cut through an identical process, the side surface 510SW of a first molding film, the side surface 520SW of a second molding film, and the outermost side surface 420SW of a shielding film structure may be disposed on an identical plane.

Then, referring to FIG. 2, the first molding film 510, the first semiconductor chip 100, the second molding film 520, and the second semiconductor chip 200 may be separated from the carrier substrate 10 (of FIG. 16), and the first molding film 510, the first semiconductor chip 100, the second molding film 520, and the second semiconductor chip 200 may be formed above the redistribution substrate 50 so as to be electrically connected to the redistribution substrate 50.

The various example embodiments of the present disclosure have been described above in detail, but the scope of the present disclosure is not limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

What is claimed is:

1. A semiconductor package comprising:
a first semiconductor chip;
a second semiconductor chip above the first semiconductor chip;
a shielding wall structure surrounding the first semiconductor chip at a side of the first semiconductor chip;
a shielding film structure extending along a side surface of the second semiconductor chip and an upper surface of the second semiconductor chip;
a first chip bonding pad between the first semiconductor chip and the second semiconductor chip and adjacent to an upper portion of the first semiconductor chip; and
a second chip bonding pad between the first semiconductor chip and the second semiconductor chip and adjacent to a lower portion of the second semiconductor chip.

2. The semiconductor package of claim 1, further comprising a wiring post at the side of the first semiconductor chip, the wiring post being electrically connected to the first semiconductor chip.

3. The semiconductor package of claim 2, wherein the wiring post is between the first semiconductor chip and the shielding wall structure.

4. The semiconductor package of claim 1, further comprising a passivation film extending along the side surface of the second semiconductor chip and the upper surface of the second semiconductor chip, the passivation film being covered by the shielding film structure.

5. The semiconductor package of claim 4, further comprising a shielding connection pad on the shielding wall structure, and
wherein the shielding film structure comprises a connection part penetrating the passivation film and connected to the shielding connection pad.

6. The semiconductor package of claim 1, wherein, above a lower surface of the first semiconductor chip, an upper surface of the first semiconductor chip is lower than an upper surface of the shielding wall structure.

7. The semiconductor package of claim 6, wherein the first semiconductor chip comprises a first chip penetration via penetrating the upper surface of the first semiconductor chip, and
wherein an upper surface of the first chip penetration via and the upper surface of the shielding wall structure are on a same plane.

8. The semiconductor package of claim 1, wherein, when viewed from an upper surface of the first semiconductor chip, the shielding wall structure has a ring shape and surrounds the first semiconductor chip.

9. The semiconductor package of claim 1, further comprising a first molding film surrounding the first semiconductor chip and the shielding wall structure.

10. The semiconductor package of claim 9, wherein an outermost side surface of the shielding film structure and a side surface of the first molding film are on a same plane.

11. The semiconductor package of claim 1, further comprising a second molding film at a side of the second semiconductor chip above the first semiconductor chip, and
wherein an upper surface of the second molding film and an upper surface of the shielding film structure are on a same plane.

12. The semiconductor package of claim 11, wherein an outermost side surface of the shielding film structure and a side surface of the second molding film are on a same plane.

13. A semiconductor package comprising:
a redistribution substrate comprising a redistribution layer;
a first semiconductor chip on the redistribution substrate;
a first molding film surrounding the first semiconductor chip on the redistribution substrate;
a second semiconductor chip above the first semiconductor chip;
a passivation film extending along a side surface of the second semiconductor chip and an upper surface of the second semiconductor chip above the first molding film;
a shielding wall structure penetrating the first molding film and surrounding a side surface of the first semiconductor chip, the shielding wall structure being connected to the redistribution layer;
a shielding film structure extending along the passivation film above the side surface of the second semiconductor chip and the upper surface of the second semiconductor chip, the shielding film structure being connected to the shielding wall structure; and
a second molding film covering the shielding film structure above the first molding film.

14. The semiconductor package of claim 13, wherein an outermost side surface of the shielding film structure is covered by the second molding film.

15. The semiconductor package of claim 13, further comprising:
a first chip bonding pad between the first semiconductor chip and the second semiconductor chip, the first chip bonding pad being adjacent to an upper portion of the first semiconductor chip; and
a second chip bonding pad between the first semiconductor chip and the second semiconductor chip and adjacent to a lower portion of the second semiconductor chip, the second chip bonding pad contacting the first chip bonding pad.

16. The semiconductor package of claim 15, wherein the first semiconductor chip comprises a first chip penetration via electrically connected to the first chip bonding pad and penetrating an upper surface of the first semiconductor chip.

17. The semiconductor package of claim 13, wherein a first width of the first semiconductor chip is smaller than a second width of the second semiconductor chip.

18. The semiconductor package of claim 13, wherein the shielding wall structure comprises:
a first shielding wall surrounding the side surface of the first semiconductor chip; and
a second shielding wall surrounding an outer side surface of the first shielding wall.

19. The semiconductor package of claim 13, wherein the second semiconductor chip comprises a plurality of memory dies.

20. A semiconductor package comprising:
a redistribution substrate;
a first semiconductor chip on the redistribution substrate;
a shielding wall structure on the redistribution substrate and surrounding a side surface of the first semiconductor chip;
a second semiconductor chip above the first semiconductor chip;
a wiring post between the first semiconductor chip and the shielding wall structure and electrically connecting the redistribution substrate and the second semiconductor chip;
a passivation film extending along a side surface of the second semiconductor chip and an upper surface of the second semiconductor chip;
a shielding film structure extending along the passivation film and connected to the shielding wall structure;
a first chip penetration via penetrating at least a portion of the first semiconductor chip and connected to the second semiconductor chip;
a first chip bonding pad between the first semiconductor chip and the second semiconductor chip and connected to the first chip penetration via; and
a second chip bonding pad between the first semiconductor chip and the second semiconductor chip and adjacent to a lower portion of the second semiconductor chip, the second chip bonding pad contacting the first chip bonding pad.
